(19) United States
(12) Patent Application Publication
(10) Pub. No.: US 2004/0042189 A1
(43) Pub. Date: Mar. 4, 2004

(54) Multi-chip integrated module

(76) Inventor: Yuan-Jen Chao, Kaohsiung (TW)

Correspondence Address: BIRCH STEWART KOLASCH & BIRCH, PO BOX 747, FALLS CHURCH, VA, 22040-0747, US

(21) Appl. No.: 10/648,253

(22) Filed: Aug. 27, 2003

(30) Foreign Application Priority Data
Aug. 27, 2002 (TW) 091119466

(51) Int. Cl. H05K 1/18

(52) U.S. Cl. 361/764

(57) ABSTRACT

A multi-chip integrated module includes a transparent substrate, at least two chips, and a circuit substrate. In this case, a circuit layer is formed on one surface of the transparent substrate, wherein the circuit layer formed on the surface of the transparent substrate includes a circuit for electrical inter-connection and a plurality of electrical pads for electrical external-connection. The chips are mounted on the transparent substrate by way of a flip-chip bonding, respectively. Thus, the chips and the circuit for electrical inter-connection construct a circuit system. The circuit substrate attaches to the transparent substrate, on which the chips are mounted. The circuit substrate at least includes a circuit layer, which electrically connects to the electrical pads of the transparent substrate. Furthermore, an additional multi-chip integrated module is also disclosed.

### BACKGROUND OF THE INVENTION

1. Field of Invention

The invention relates to a multi-chip integrated module, and in particular, to a multi-chip integrated module, which includes a transparent substrate.

2. Related Art

As electrical systems increase in functionality and become more compact, conventional IC packaging and PCBs (printed circuit boards) assembling technologies are no longer able to satisfy the demand for reduced system size. As a result, an obvious trend is to integrate multiple complex functions in a single IC chip or package.

Regarding to the case of integrating multiple complex functions in a single IC chip, if the functions of the IC chip serve as a system, the single IC chip can be called an SoC (system on chip). Although the SoC has advantages, it has many disadvantages, which are:

1. The first silicon time is a lengthy process. That is, as IC designs become more complex, IC design development time increases accordingly; as a result the first chips often cannot meet marketing demands in time.

2. Intellectual Property (IP) must be purchased from external providers. That is, the manufacturer may have to purchase or license SIP Silicon Intellectual Property).

3. Integration of different functions and manufacturing processes in a single chip is difficult. In general, performance of chips with integrated functions degrades.

4. It is difficult to test the SoC.

5. The SoC has lower yield.

Considering the above-mentioned disadvantages, manufacturers have developed the technology for assembling different chips in a single package, which is called an MCP (multi-chip package) technology or an MCM (multi-chip module) technology. As MCP technology developed over time, IC chips located in one package can serve as an entire system. Such products with multiple-chip packages are also known as Systems in Package (SIP). Although the MCP, MCM, or SIP offers many advantages over SoCs, there are also several disadvantages including:

1. For a common MCP, MCM, or SIP, a substrate providing high-density inter-connection is required, and the manufacturing cost thereof is high.

2. If the multiple chips are packaged by way of stacked die, there will be limitations on the chip sizes.

3. In the case of high pin-count, packaging multiple chips is difficult.

As mentioned above, integrating multiple chips into a single chip and integrating multiple chips in a package both have practical disadvantages, thus it is an important subjective to provide a multi-chip integrating technique to solve the above-mentioned disadvantages.

### SUMMARY OF THE INVENTION

In view of the above-mentioned problems, an objective of the invention is to go beyond conventional thinking regarding SoC and SIP technologies, and focus on the substrate material and further exploit the chip-integration technology.

It is therefore an objective of the invention to provide a multi-chip integrated module, which enables short product development time, is easy to be tested, has high yield, has no chip size limitation, has good high frequency properties, has good heat dissipation performance, and has high reliability.

It is another objective of the invention to provide an additional multi-chip integrated module, which enables short product development time, is easy to be tested, provides high yield, has high pin-count, has no chip size limitation, has good high frequency properties, has good heat dissipation performance, has high reliability, and has lower manufacturing cost.

To achieve the above-mentioned objectives, a multi-chip integrated module includes a transparent substrate, at least two chips, and a circuit substrate. In the invention, the transparent substrate includes a circuit layer formed on one surface of the transparent substrate. The circuit layer formed on one surface of the transparent substrate includes a circuit for electrical inter-connection and a plurality of electrical pads. The chips are respectively attached to the transparent substrate by way of a flip-chip bonding, so that the chips and the circuit for electrical inter-connection construct a circuit system. The circuit substrate including at least one circuit layer attaches to the transparent substrate, on which the chips are mounted. The electrical pads of the transparent substrate electrically connect to the circuit layer of the circuit substrate. It should be noted that the circuit substrate might further include a hollow portion, so that when the circuit substrate attaches to the transparent substrate, the chips are positioned in the hollow portion of the circuit substrate.

In such a case, since the transparent substrate can be a glass substrate, which has a thermal expansion coefficient similar to that of the silicon material of the chips, the sizes and pitches of the circuit for electrical inter-connection on the transparent substrate can be of the same level as the sizes and pitches on the chips. That is to say, the sizes and pitches of the circuit lines of the circuit layer formed on the transparent substrate can be reduced. Thus, the size of the transparent substrate is also reduced. In addition, since the invention provides chips having different functions on the transparent substrate by way of a flip-chip bonding, it has the advantages of short product development time, easiness of testing, providing high yield, and having no chip size limitations. Moreover, the transparent substrate, especially a glass substrate, can provide excellent insulation to reduce the decay of high frequency signals caused by parasitic capacitance and parasitic leakage resistance, so that the multi-chip integrated module of the invention has superior high frequency properties. Since the thermal expansion coefficients of the glass substrate and the semiconductor chip are similar, the poor reliability resulting from the different thermal expansion coefficients of the internal elements of the multi-chip packaging is improved. In addition, since each chip is attached to the transparent substrate by way of a flip-chip bonding, heat can dissipate through the backside of each chip. The circuit substrate includes a hollow portion, so that the chips can be positioned in the hollow portion of the circuit substrate. Therefore, the multi-chip integrated module of the invention has greatly improved heat dissipation performance. Of course, if the circuit substrate is a conventional printed circuit board, the manufacturing cost of the multi-chip integrated module of the invention can also be reduced.

Additionally, the invention also provides another multi-chip integrated module, which includes a transparent substrate, and at least two chips. In this case, the transparent substrate has a circuit layer formed on one surface of the transparent substrate, which includes a circuit for electrical inter-connection and a plurality of electrical pads for electrical external-connection. A plurality of bumps are formed on a part of the circuit for electrical inter-connection. The chips electrically connect to the bumps of the circuit for electrical inter-connection by way of a flip-chip bonding, respectively. Accordingly, the chips and the circuit for electrical inter-connection construct a circuit system. Furthermore, a plurality of bumps can further be formed on the electrical pads for the needs of electrically connecting to external devices.

In this case, since the transparent substrate can be a glass substrate, which has a thermal expansion coefficient similar to that of a silicon material of the chips, the sizes and pitches of the circuit for electrical inter-connection on the transparent substrate can be of the same level as the sizes and pitches on the chips. That is to say, the sizes and pitches of the circuit lines of the circuit layer formed on the transparent substrate can be reduced. Thus, the size of the transparent substrate is also reduced. In addition, since the invention provides chips having different functions on the transparent substrate by way of a flip-chip bonding, it has the advantages of short product development time, easiness of testing, providing high yield, and having no chip size limitations. Moreover, the transparent substrate, especially a glass substrate, provides excellent insulation to reduce the decay of high frequency signals caused by parasitic capacitance and parasitic leakage resistance, so that the multi-chip integrated module of the invention has superior high frequency properties. Since the thermal expansion coefficients of the glass substrate and the semiconductor chip are similar, the poor reliability resulting from the different thermal expansion coefficients of the internal elements of the multi-chip packaging is improved. Additionally, since each chip and the circuit for electrical inter-connection on the transparent substrate construct a circuit system, and a plurality of bumps are preformed on the electrical pads, the multi-chip integrated module of the invention can have a two-dimensional bumps arrangement similar to the conventional BGA packaging technology. In other words, the multi-chip integrated module of the invention can achieve high pin-count functions. Furthermore, since each chip is formed on the transparent substrate by way of a flip-chip bonding, heat can dissipate through the backside of each chip. That is, the multi-chip integrated module of the invention has excellent heat dissipation performance. Moreover, since the transparent substrate can be a glass substrate, which offers lower cost than other substrates, the manufacturing cost of the multi-chip integrated module of the invention is reduced. Since the bumps for electrically connecting to the chips are formed on a part of the circuit for electrical inter-connection, it is unnecessary to form additional bumps on each chip. Therefore, the manufacturing cost of the multi-chip integrated module of the invention may be further reduced.

### BRIEF DESCRIPTION OF THE DRAWINGS

The present invention can be more fully understood by reading the subsequent detailed description and examples with references made to the accompanying drawings, wherein:

FIG. 1A is a schematic illustration showing a cross-section side view of a multi-chip integrated module according to a preferred embodiment of the invention, wherein the chips are attached to the transparent substrate with an ACF (Anisotropic Conductive Film);

FIG. 1B is a schematic illustration showing an enlarged view of the dotted circular area shown in FIG. 1A;

FIG. 1C is a schematic illustration showing another enlarged view of the dotted circular area shown in FIG. 1A;

FIG. 2 is a schematic illustration showing another cross-section side view of a multi-chip integrated module according to a preferred embodiment of the invention, wherein the chips are attached to the transparent substrate with an ACF, and the transparent substrate is mounted on the circuit substrate with solder bumps;

FIG. 3 is a schematic illustration showing another cross-section side view of a multi-chip integrated module according to a preferred embodiment of the invention, wherein the chips are attached to the transparent substrate with solder bumps, and the transparent substrate is mounted on the circuit substrate with solder bumps;

FIG. 4 is a schematic illustration showing an additional cross-section side view of a multi-chip integrated module according to a preferred embodiment of the invention, wherein the circuit substrate does not include a hollow portion;

FIG. 5 is a schematic illustration showing another cross-section side view of a multi-chip integrated module according to a preferred embodiment of the invention, wherein the circuit substrate does not include a hollow portion;

FIG. 6 is a schematic illustration showing an additional cross-section side view of a multi-chip integrated module according to a preferred embodiment of the invention, wherein a heat dissipation element is formed on the backside of each chip;

FIG. 7 is a schematic illustration showing another cross-section side view of a multi-chip integrated module according to a preferred embodiment of the invention, wherein a passive component or an active component is formed on the transparent substrate, and a heat dissipation element is formed on the backside of each chip;

FIG. 8A is a schematic illustration showing a cross-section side view of a multi-chip integrated module according to another preferred embodiment of the invention, wherein a plurality of bumps, such as gold bumps or solder bumps, are formed on the transparent substrate;

FIG. 8B is a schematic illustration showing an enlarged view of the dotted circular area shown in FIG. 8A;

FIG. 9 is a schematic illustration showing another cross-section side view of a multi-chip integrated module according to another preferred embodiment of the invention, wherein a plurality of bumps, such as solder bumps, are formed on the circuit for electrical inter-connection on the transparent substrate;

FIG. 10 is a schematic illustration showing another cross-section side view of a multi-chip integrated module according to another preferred embodiment of the invention, wherein a plurality of bumps, such as gold bumps or copper bumps, are formed on the electrical pads of the transparent substrate, and a passive component or an active component is formed on the transparent substrate;

FIG. 11 is a schematic illustration showing an additional cross-section side view of a multi-chip integrated module according to another preferred embodiment of the invention, wherein a plurality of bumps, such as solder bumps, are formed on the electrical pads of the transparent substrate, and a passive component or an active component is formed on the transparent substrate; and

FIG. 12 is a schematic illustration showing another cross-section side view of a multi-chip integrated module according to another preferred embodiment of the invention, wherein a plurality of bumps, such as solder bumps, are formed on the circuit for electrical inter-connection, other bumps, such as solder bumps, are formed on the electrical pads of the transparent substrate, and a passive component or an active component is formed on the transparent substrate.

### DETAILED DESCRIPTION OF THE INVENTION

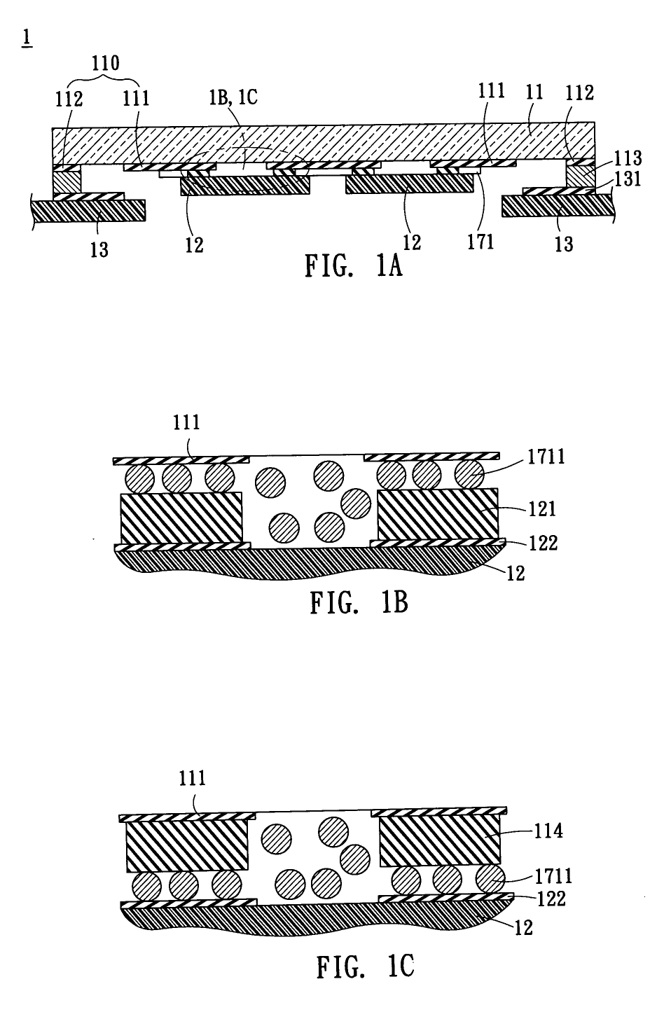

The multi-chip integrated module according to the preferred embodiments of the invention will be described herein below with reference to the FIG. 1 to FIG. 7, wherein the same reference numbers refer to the same elements.

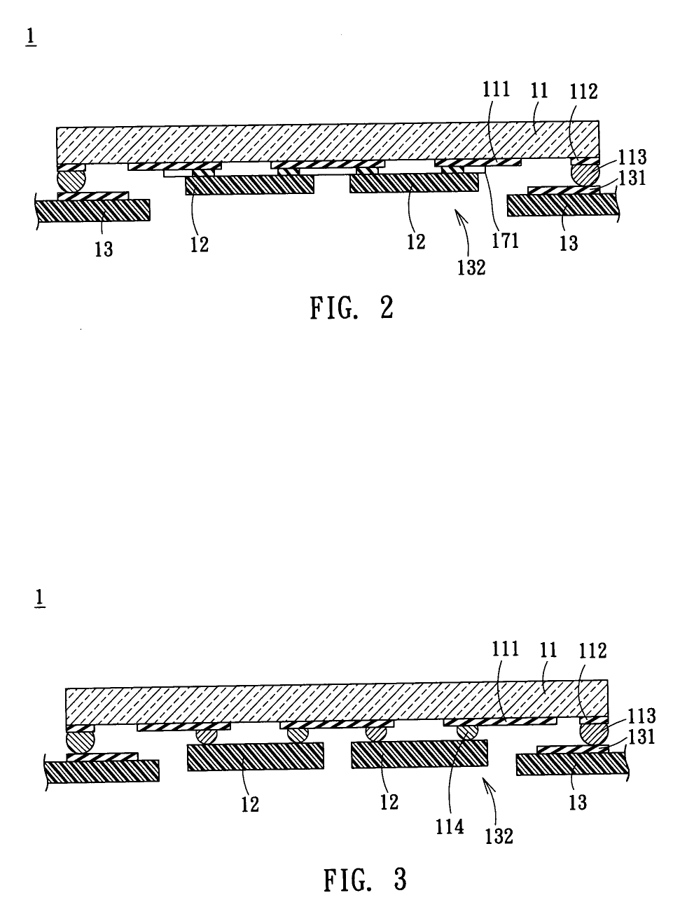

As shown in FIG. 1A, FIG. 2 and FIG. 3, a multi-chip integrated module 1 according to a preferred embodiment of the invention includes a transparent substrate 11, at least two chips 12 and 12, and a circuit substrate 13.

The transparent substrate 11 has a surface, on which a circuit layer 110 is formed. The circuit layer 110 has a circuit 111 for electrical inter-connection and a plurality of electrical pads 112. In the invention, the transparent substrate 11 is a glass substrate, and a plurality of bumps 113 are formed on the electrical pads 112, respectively. As shown in FIG. 2 and FIG. 3, the bumps 113 are solder bumps; otherwise, as shown in FIG. 1, the bumps 113 can be gold bumps or copper bumps.

The chips 12 are respectively attached to the transparent substrate 11 by way of a flip-chip bonding, so that the chips 12 and the circuit 111 for electrical inter-connection construct a circuit system. In the invention, as shown in FIG. 1B and FIG. 1C, the flip-chip bonding may employ an ACF (Anisotropic Conductive Film) 171 for connecting and attaching the chip 12 to the transparent substrate 11. Additionally, as shown in FIG. 1B, when the chip 12 is attached to the transparent substrate 11, a plurality of bumps 121, such as gold bumps, are formed on the electrical pads 122 of the chip 12 in advance. Then, a plurality of conductive particles 1711, such as gold particles, in the ACF 171 can electrically connect the circuit 111 for electrical inter-connection on the transparent substrate 11 to the bumps 121. Alternatively, as shown in FIG. 1C, a plurality of bumps 114, such as gold bumps, are formed on the circuit 111 for electrical inter-connection on the transparent substrate 11. Then, the bumps 114 electrically connect to the chip 12 through the conductive particles 1711, such as gold particles, of the ACF 171. Except for the mentioned ACF, the flip-chip bonding can also employ solder bumps to provide electrical connection. As shown in FIG. 3, a plurality of solder bumps 114 are formed on the circuit 111 for electrical inter-connection on the transparent substrate 11 in advance, and the dies 12 are then attached to the circuit 111 for electrical inter-connection on the transparent substrate 11. Of course, any other flip-chip bonding method can be utilized in the invention, and description of other methods is omitted herein.

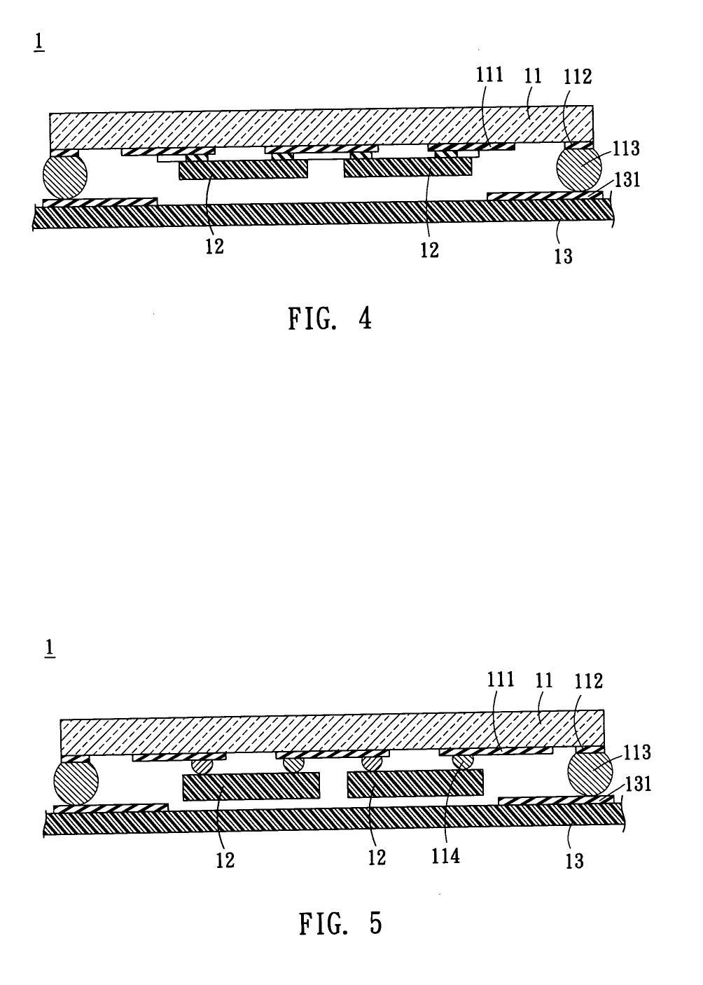

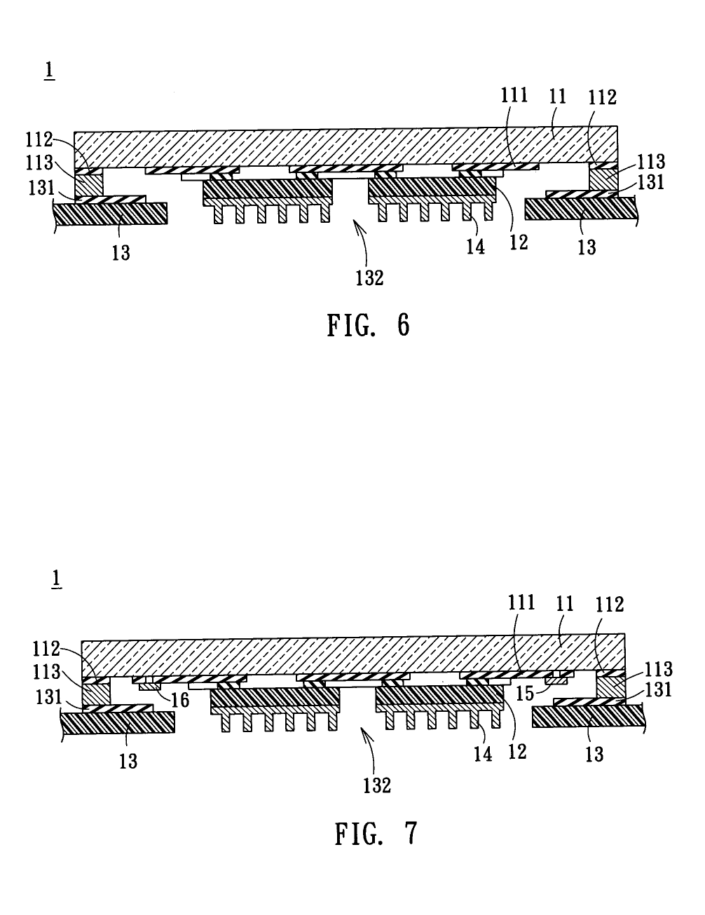

The circuit substrate 13 attaches to the transparent substrate 11, to which the chips 12 are attached. The circuit substrate 13 includes at least a circuit layer 131. The transparent substrate 11, to which the chips 12 are attached, electrically connects to the circuit layer 131 of the circuit substrate 13 through the electrical pads 112. In the present embodiment, the electrical pads 112 electrical connect to the circuit layer 131 through the bumps 113 formed on the electrical pads 112. The circuit substrate 13 of the embodiment is a common PCB, a FPC or a PWB. The common PCB, FPC and PWB are both referred to as a printed circuit substrate in the following. It should be noted that the circuit substrate 13 further includes a hollow portion 132. Thus, when the transparent substrate 11 is mounted on the circuit substrate 13, the chips 12 are positioned in the hollow portion 132. Additionally, if heat dissipation performance is not a concern, the hollow portion in the circuit substrate 13 (as shown in FIG. 4 and FIG. 5) is not required. In such a case, however, the bumps 113 formed on the electrical pads 112 must be larger, so as to prevent the chips 12 from contacting the circuit substrate 13. Moreover, as shown in FIG. 6, when the circuit substrate 13 contains the hollow portion 132, a heat dissipation element 14 can be formed on a backside of each chip 12. Therefore, the heat dissipation performance is enhanced.

Furthermore, as shown in FIG. 7, in the current embodiment, when the chips 12 and the circuit 111 for electrical inter-connection construct a circuit system, a passive component 15 or an active component 16 may be formed on the circuit 111. Therefore, a circuit system with powerful functions can be designed, or the manufactured product can be tested easier.

As mentioned above, regarding the multi-chip integrated module according to the embodiment, since the transparent substrate 11 is a glass substrate, which has a thermal expansion coefficient similar to that of the silicon material of the chips 12, the sizes and pitches of the circuit 111 for electrical inter-connection on the transparent substrate 11 can be formed with the same level as the sizes and pitches on the chips. That is to say, the sizes and pitches of the circuit lines of the circuit layer formed on the transparent substrate 11 can be relatively small, so that the size of the transparent substrate 11 is reduced. Additionally, since the invention provides chips having different functions on the transparent substrate 11 by way of a flip-chip bonding, it has the advantages of short product development time, easiness of testing, providing high yield, and having no chip size limitations. Moreover, the transparent substrate 11, especially a glass substrate, provides an excellent insulation property and reduces the decay of high frequency signals caused by parasitic capacitance and parasitic leakage resistance, so that the multi-chip integrated module of the invention has superior high frequency properties. Since the thermal expansion coefficients of the glass substrate and the semiconductor chip are similar, the poor reliability resulting from the different thermal expansion coefficients of the internal elements of the multi-chip package is greatly improved. Additionally, since each chip 12 is formed on the transparent substrate 11 by way of a flip-chip bonding, and the circuit substrate 13 has a hollow portion 132 for containing the chips 12, heat dissipates through the backside of each chip 12. Furthermore, since a heat dissipation element 14 is provided on the backside of each chip 12, heat dissipation is greatly enhanced. Of course, if the circuit substrate is a conventional printed circuit substrate, the manufacturing cost of the multi-chip integrated module of the invention can be reduced properly. It should be noted that since the transparent substrate 11 is transparent, when the chips 12 are attached to the transparent substrate 11, or when the transparent substrate 11 is mounted on the circuit substrate 13 utilizing SMT technologies, the product could be inspected for defects easily. Thus, the product yield and reliability of the invention are significantly enhanced, which conventional packaging technologies, such as BGA packages, cannot achieve due to the opaque property of the conventional substrate used for packaging.

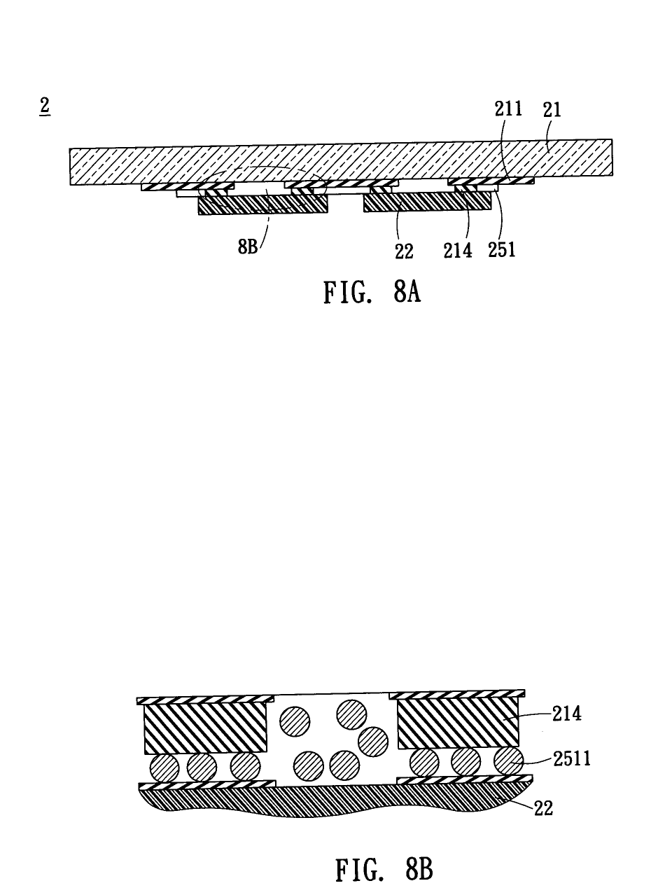

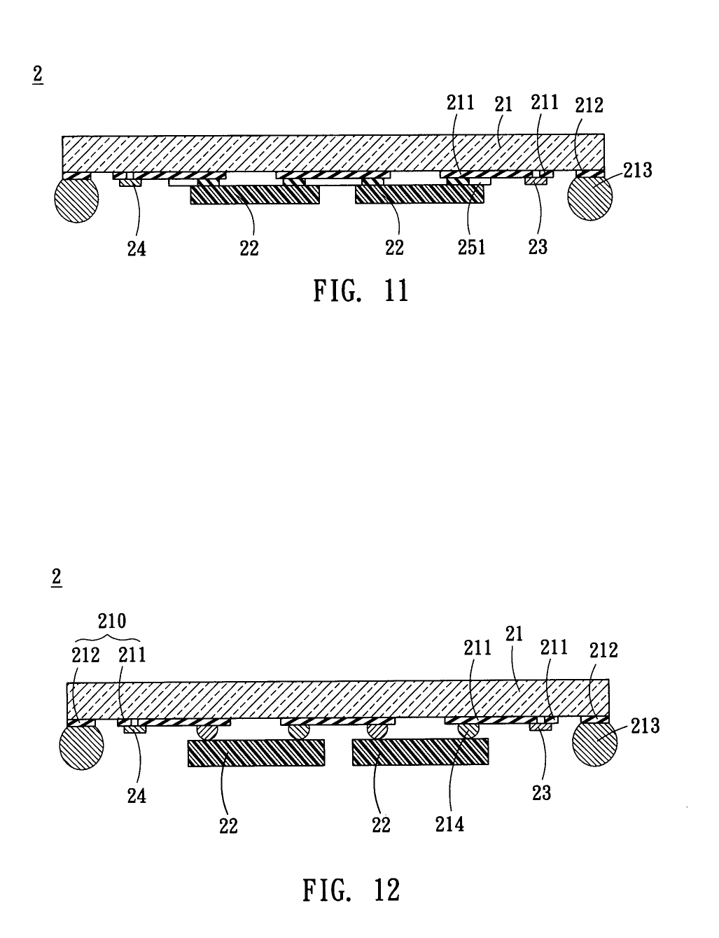

The multi-chip integrated module according to another preferred embodiment of the invention is described in the following with reference to FIGS. 8 to 12, wherein the same reference numbers refer to the same elements. In this embodiment, some elements are the same as those disclosed in the former embodiment, thus their description is omitted.

As shown in FIGS. 8 to 12, a multi-chip integrated module 2 according to another preferred embodiment of the invention includes a transparent substrate 21, and at least two chips 22 and 22.

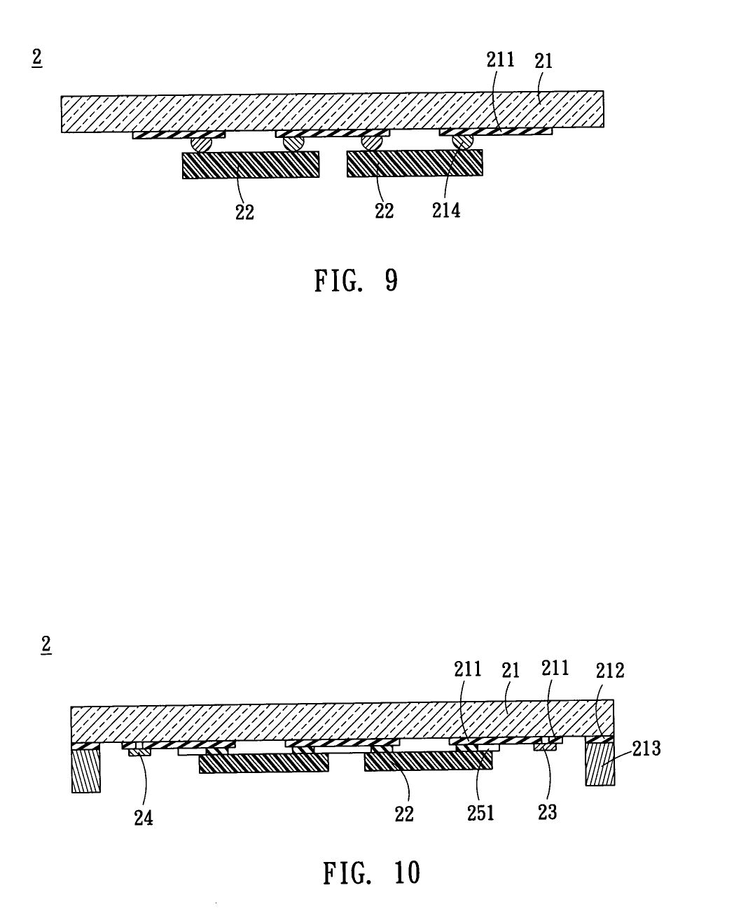

The transparent substrate 21 has a surface, on which a circuit layer 210 is formed. The circuit layer 210 has a circuit 211 for electrical inter-connection. As shown in FIG. 8A, FIG. 8B and FIG. 9, a plurality of bumps 214 are formed on a part of the circuit 211 for electrical inter-connection. Additionally, as shown in FIG. 10 to FIG. 12, for electrically connecting to external devices, the circuit layer 210 further includes a plurality of electrical pads 212 for electrical external-connection. A plurality of bumps 213 are formed on the electrical pads 212, respectively. In the invention, the transparent substrate 21 is a glass substrate, and the bumps 213 are solder bumps, gold bumps, or copper bumps. The bumps 214 are solder bumps or gold bumps.

The chips 22 are respectively attached to the transparent substrate 21 by way of a flip-chip bonding, and electrically connect to the bumps 214 of the circuit 211 for electrical inter-connection. Thus, the chips 22 and the circuit 211 for electrical inter-connection construct a circuit system. As shown in FIG. 8A, the flip-chip bonding may employ an ACF 251 for connecting and attaching the chip 22 to the transparent substrate 21. In addition, as shown in FIG. 8B, to attach and connect the chip 22 to the transparent substrate 21, a plurality of bumps 214, such as gold bumps, are formed on the circuit 211 for electrical inter-connection on the transparent substrate 21. Then, a plurality of conductive particles 2511, such as gold particles, in the ACF 251 can electrically connect the circuit 211 to the chip 22. Except for the mentioned ACF, the flip-chip bonding can also employ solder bumps for electrical connection. As shown in FIG. 9, the bumps 214 formed on the circuit 211 for electrical inter-connection on the transparent substrate 21 are solder bumps. Of course, any other flip-chip bonding method can be utilized in the invention. Furthermore, as shown in FIG. 10 to FIG. 12, in the current embodiment, when the chips 22 and the circuit 211 for electrical inter-connection construct a circuit system, at least one passive component 23 or at least one active component 24 may be formed on the circuit 211. Therefore, a circuit system with powerful functions can be designed, or the manufactured product can be tested easier.

As mentioned above, regarding the multi-chip integrated module according to the embodiment, since the transparent substrate 21 is a glass substrate, which has a thermal expansion coefficient similar to that of the silicon material of the chips 22, the sizes and pitches of the circuit 211 for electrical inter-connection on the transparent substrate 21 can be formed with the same level as the sizes and pitches on the chips. That is to say, the sizes and pitches of the circuit lines of the circuit layer formed on the transparent substrate 21 can be relatively small, so that the size of the transparent substrate 21 is reduced. Additionally, since the invention provides chips having different functions on the transparent substrate 21 by way of a flip-chip bonding, it has the advantages of short product development time, easiness of testing, providing high yield, and having no chip size limitations. Moreover, the transparent substrate 21, especially a glass substrate, provides excellent insulation properties to reduce the decay of high frequency signals caused by parasitic capacitance and parasitic leakage resistance, so that the multi-chip integrated module of the invention has superior high frequency properties. Since the thermal expansion coefficients of the glass substrate and the semiconductor chip are similar, the poor reliability resulting from the different thermal expansion coefficients of the internal elements of the multi-chip package is greatly improved. Additionally, since the chips 22 and the circuit 211 for electrical inter-connection on the transparent substrate 21 construct a circuit system, and a plurality of bumps 213 are preformed on the electrical pads 212, the multi-chip integrated module of the invention can have a two-dimensional bumps arrangement similar to the conventional BGA packaging technology. In other words, the multi-chip integrated module of the invention can achieve high pin-count functions. Furthermore, since each chip 22 is formed on the transparent substrate 21 by way of a flip-chip bonding, heat can dissipate through the backside of each chip 22. That is, the multi-chip integrated module of the invention has excellent heat dissipation performance. Moreover, since the transparent substrate 21 can be a glass substrate, which is far more cost effective than other substrates, the manufacturing cost of the multi-chip integrated module of the invention is greatly reduced. Since the bumps for electrically connecting to the chips are formed on a part of the circuit for electrical inter-connection, it is unnecessary to form additional bumps on each chip. Therefore, the manufacturing cost of the multi-chip integrated module of the invention may be further reduced. It should be noted that since the transparent substrate 21 is transparent, when the chips 22 are attached to the transparent substrate 21, or when the transparent substrate 21 is mounted on a circuit substrate utilizing SMT technologies, the product could be inspected for defects easily. Thus, the product yield and reliability of the invention are significantly enhanced over conventional packaging technologies, such as BGA packages, which cannot achieve similar results due to the opaque property of the conventional substrate used for packaging.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A multi-chip integrated module, comprising:
a transparent substrate, which has a circuit layer formed on one surface of the transparent substrate, wherein the circuit layer formed on the surface of the transparent substrate comprises a circuit for electrical inter-connection and a plurality of electrical pads;
at least two chips, which are respectively mounted on the transparent substrate by way of a flip-chip bonding, wherein the chips and the circuit for electrical inter-connection construct a circuit system; and
a circuit substrate, which attaches to the transparent substrate, and at least comprises a circuit layer of the circuit substrate, wherein the electrical pads of the transparent substrate electrically connect to the circuit layer of the circuit substrate.

2. The multi-chip integrated module of claim 1, wherein the transparent substrate is a glass substrate.

3. The multi-chip integrated module of claim 1, wherein a plurality of bumps are formed on the electrical pads of the transparent substrate, respectively, for electrically connecting the electrical pads and the circuit layer of the circuit substrate.

4. The multi-chip integrated module of claim 1, wherein a plurality of bumps are formed on a part of the circuit for electrical inter-connection, and the chips electrically connect to the bumps by way of a flip-chip bonding.

5. The multi-chip integrated module of claim 3 or 4, wherein the bumps are solder bumps.

6. The multi-chip integrated module of claim 3 or 4, wherein the bumps are gold bumps.

7. The multi-chip integrated module of claim 3, wherein the bumps are copper bumps.

8. The multi-chip integrated module of claim 1, wherein the circuit substrate has a hollow portion, and when the circuit substrate attaches to the transparent substrate, the chips are positioned in the hollow portion of the circuit substrate.

9. The multi-chip integrated module of claim 8, wherein a heat dissipation element is formed on the backside of at least one of the chips.

10. The multi-chip integrated module of claim 1, wherein the circuit substrate is a printed circuit substrate.

11. The multi-chip integrated module of claim 1, further comprising:
a passive component, which is formed on the transparent substrate and electrically connects to the circuit for electrical inter-connection on the transparent substrate.

12. The multi-chip integrated module of claim 1, further comprising:
an active component, which is formed on the transparent substrate and electrically connects to the circuit for electrical inter-connection on the transparent substrate.

13. A multi-chip integrated module, comprising:
a transparent substrate, which has a circuit layer formed on one surface of the transparent substrate, wherein the circuit layer formed on the surface of the transparent substrate comprises a circuit for electrical inter-connection, and a plurality of bumps are formed on a part of the circuit for electrical inter-connection; and
at least two chips, which electrically connect to the bumps of the circuit for electrical inter-connection by way of a flip-chip bonding, wherein the chips and the circuit for electrical inter-connection construct a circuit system.

14. The multi-chip integrated module of claim 13, wherein the circuit layer of the transparent substrate further comprises a plurality of electrical pads for electrical external-connection, and a plurality of bumps are formed on the electrical pads, respectively.

15. The multi-chip integrated module of claim 13, wherein the transparent substrate is a glass substrate.

16. The multi-chip integrated module of claim 13 or 14, wherein the bumps are solder bumps.

17. The multi-chip integrated module of claim 13 or 14, wherein the bumps are gold bumps.

18. The multi-chip integrated module of claim 14, wherein the bumps are copper bumps.

19. The multi-chip integrated module of claim 13, further comprising:
a passive component, which is formed on the transparent substrate and electrically connects to the circuit for electrical inter-connection on the transparent substrate.

20. The multi-chip integrated module of claim 13, further comprising:
an active component, which is formed on the transparent substrate and electrically connects to the circuit for electrical inter-connection on the transparent substrate.
